(19) United States
(12) Patent Application Publication
(10) Pub. No.: US 2023/0064706 A1
(43) Pub. Date: Mar. 2, 2023

(54) APPARATUS AND METHOD FOR MANUFACTURING SEMICONDUCTOR STRUCTURE

(71) Applicant: TAIWAN SEMICONDUCTOR MANUFACTURING COMPANY LTD., Hsinchu (TW)

(72) Inventors: CHIEN-LIN HUANG, HSINCHU (TW); YEOU-CHYI NI, HSINCHU (TW)

(21) Appl. No.: 17/461,398

(22) Filed: Aug. 30, 2021

(51) Int. Cl. H01L 21/306; B24B 37/015; H01L 21/66; H01L 21/67

(52) U.S. Cl. CPC H01L 21/30625; B24B 37/015; H01L 22/12; H01L 21/67248

(57) ABSTRACT

An apparatus and a method forming a semiconductor structure are provided. The method includes receiving a substrate; mounting the substrate to a polishing head with a side of the substrate facing a polishing pad, the polishing pad comprising a first region and a second region; grinding the substrate against the polishing pad; and adjusting a temperature of the first region and a temperature of the second region.

### BACKGROUND

In advanced semiconductor technologies, the continuing reduction in device size and increasingly complicated circuit designs have made the designing and. fabrication of integrated circuits (ICs) more challenging and costly. For producing semiconductor IC components with desirable dimensions, polishing such as chemical mechanical polishing (CMP) has been widely used. CMP has been used to remove unwanted material from semiconductor wafer surfaces between and during operations of manufacturing semiconductor wafers. However, a uniform polishing is difficult to achieve due to various factors.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale, In fact, the dimensions of the various structures may be arbitrarily increased or reduced for clarity of discussion.

FIGS. 1A-1B are schematic views showing different statuses of an apparatus for manufacturing a semiconductor structure before and during an operation, respectively, in accordance with some embodiments of the present disclosure.

FIG. 1C is a top view of the apparatus shown in FIG. 1A, in accordance with some embodiments of the present disclosure.

FIGS. 1D-1E are a schematic view and a top view, respectively, of a platen, in accordance with some embodiments of the present disclosure.

FIG. 1F is a cross-sectional view of the platen taken along line A-A in FIG. 1D, in accordance with some embodiments of the present disclosure.

FIG. 1G is a schematic view of the apparatus shown in FIG. 1A, and FIG. 1H is a top view of the polishing pad shown in FIG. 1A, in accordance with some embodiments of the present disclosure.

FIGS. 2A-2H are schematic views showing different stages for manufacturing a semiconductor structure, respectively, in accordance with some embodiments of the present disclosure.

FIG. 3 is a schematic view of an apparatus, in accordance with some embodiments of the present disclosure.

FIG. 4 is a flowchart of a method for forming a semiconductor structure, in accordance with some embodiments of the present disclosure.

FIG. 5 is a flowchart of a method for forming a semiconductor structure, in accordance with some embodiments of the present disclosure.

FIG. 6 is a flowchart of a method for forming a semiconductor structure, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range, Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

As used herein, the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

As used herein, the term “connected” may be construed as “electrically connected,” and the term “coupled” may also be construed as “electrically coupled.” “Connected” and “coupled” may also be used to indicate that two or more elements cooperate or interact with each other.

Chemical mechanical polishing (CMP) is an operation for smoothing surfaces of a layer during the formation of the layer. The CMP generally involves a hybrid of chemical etching and physical (abrasive) polishing, and thus is performed by the combination of chemical and mechanical forces. For example, the CMP operation uses a slurry including abrasives in conjunction with a polishing pad. The polishing pad and the wafer are pressed together by a polishing head. The polishing head may be rotated to removes material and tends to smooth any irregular topography on the wafer, making the wafer surface flat or planar. This flat or planar surface may facilitate formation of components thereon. As the integrated circuits (IC) need to integrate various devices, greater challenge raises for the CMP operation. The different devices have different materials, structures and feature densities on the wafer surface to be polished, which pose difficulties to uniformity control of the CMP.

In the present disclosure, a polishing apparatus and a method for forming a semiconductor structure are proposed. The method includes adjusting a temperature distribution of the polish pad. The method further includes measuring a thickness profile (i.e., surface profile) of a wafer. The thickness profile reflects how the structural features change during the polishing operation. The temperature distribution of the polishing pad may be adjusted according to the thickness profile of the wafer. With the control of the temperature distribution of the polishing pad, a uniform polished surface may be obtained.

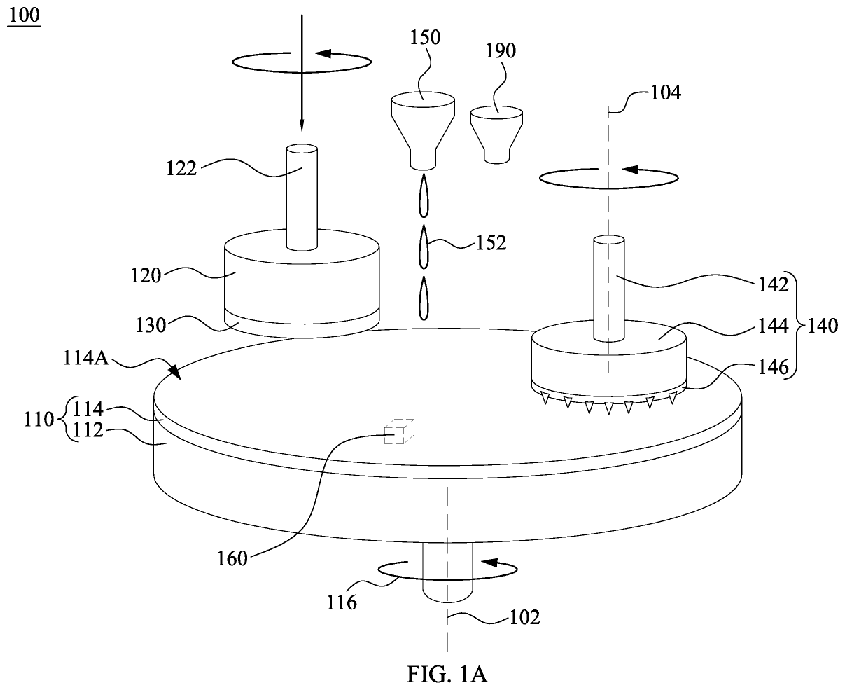

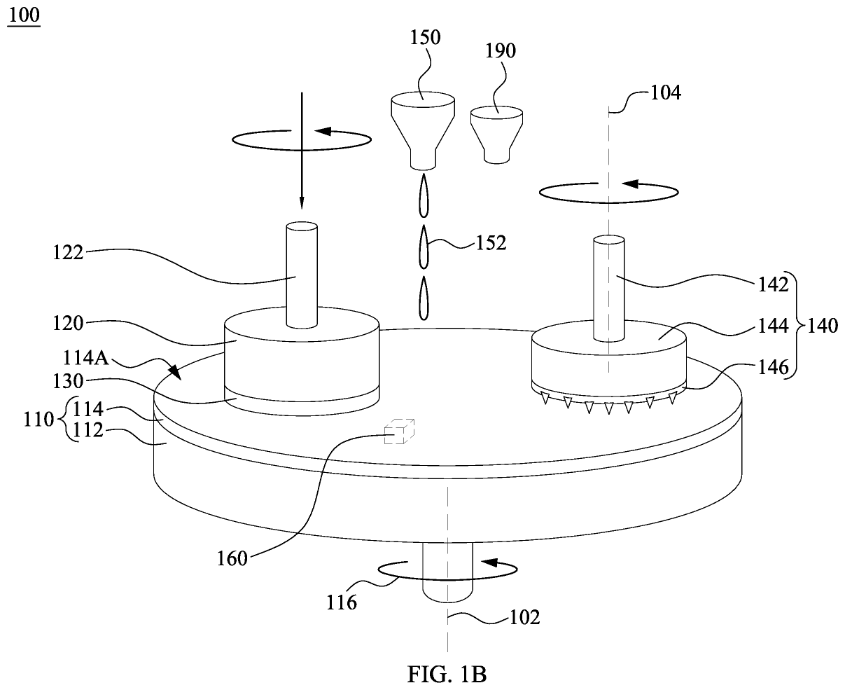

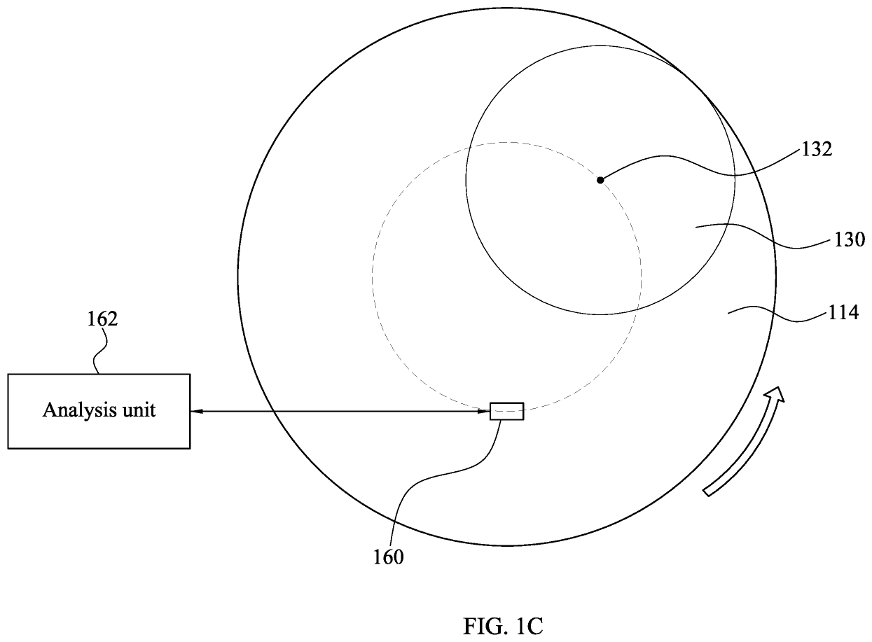

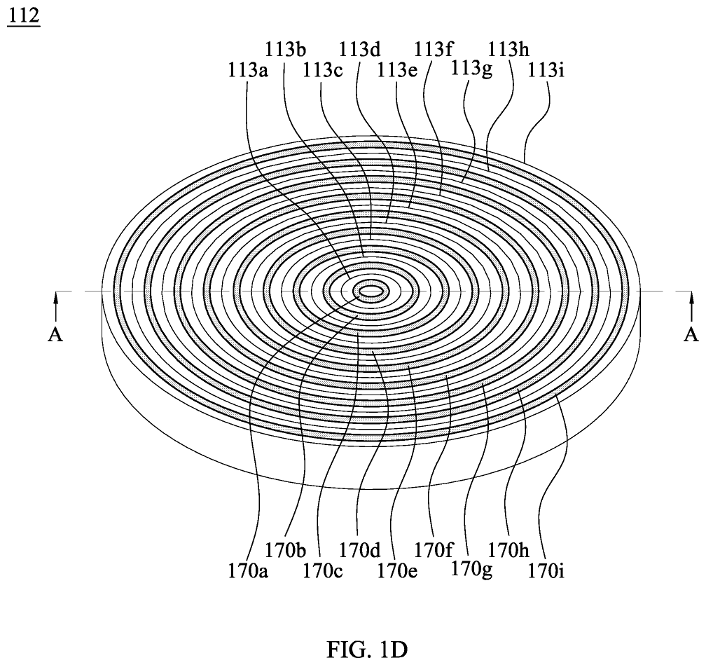

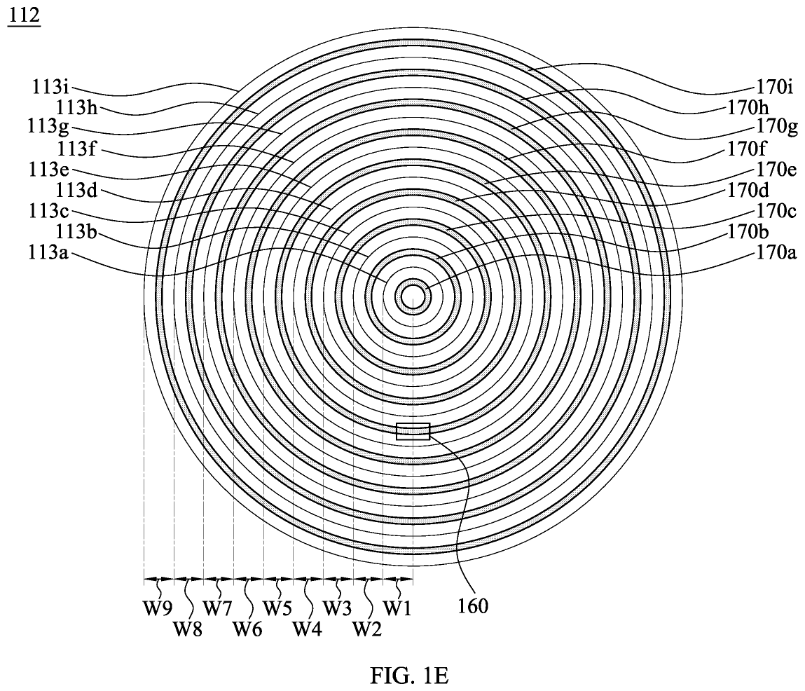

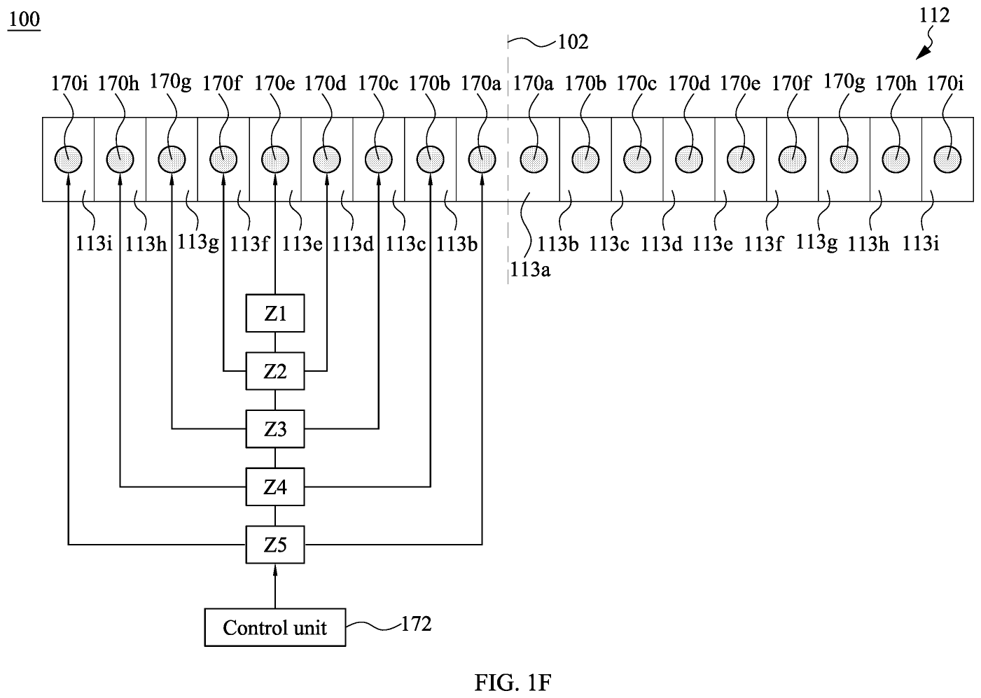

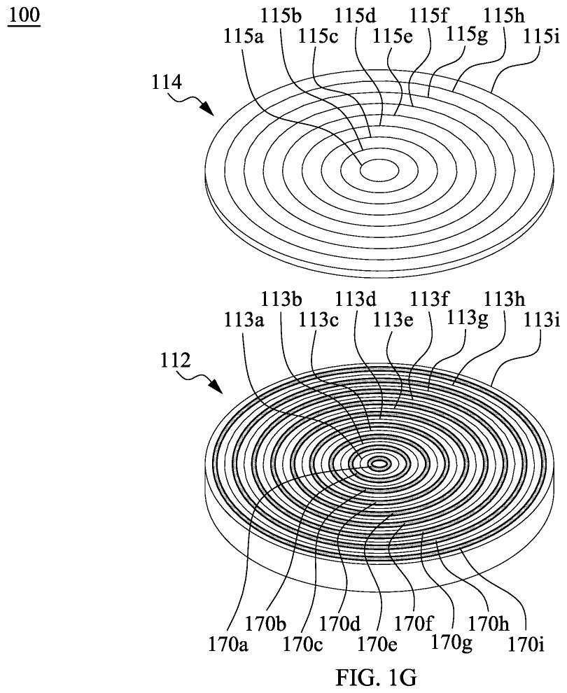

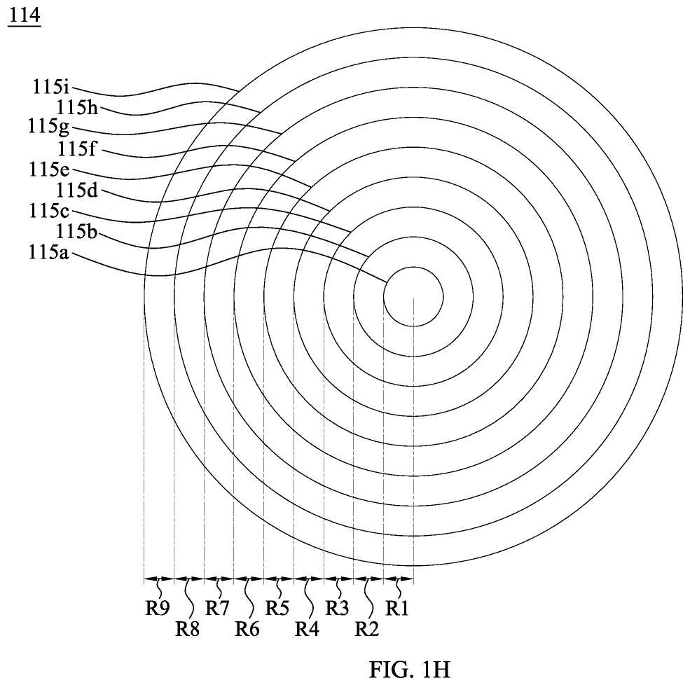

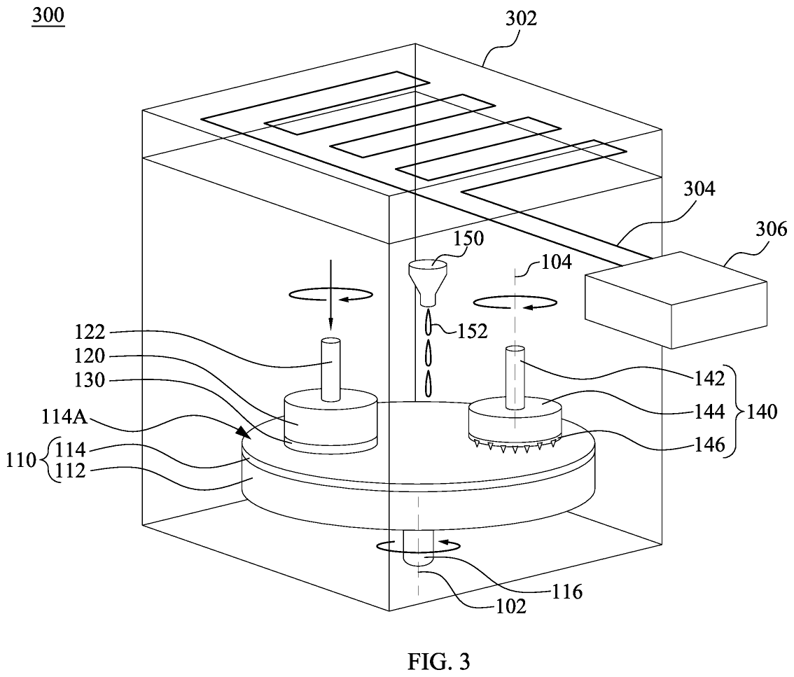

FIGS. 1A-1B are schematic views showing different statuses of an apparatus 100 for manufacturing a semiconductor structure before and during an operation, respectively, in accordance with some embodiments of the present disclosure. As depicted in FIG. 1A, the apparatus 100 includes a polishing wheel assembly 110, a polishing head 120, a pad conditioner 140 and a slurry introduction device 150. In some embodiments, the apparatus 100 further includes a measurement unit 160. In some embodiments, the apparatus 100 further includes a temperature sensor 190. In some embodiments, the apparatus 100 includes a chamber (not shown in FIG. 1A, but illustrated in FIG. 3) to accommodate the aforementioned parts.

The polishing wheel assembly 110 includes a platen 112 and a polishing pad 114. The platen 112 is coupled to a spindle (or a shaft) 116. The spindle 116 is operable to be rotated by a motor or any other suitable driving mechanism. The polishing pad 114 is arranged on the platen 112 and is configured to be rotated by the platen 112. The polishing pad 114 is attached to the platen 112, and thus is able to be rotated along with the platen 112. In some embodiments, the polishing pad 114 includes a polishing surface 114A facing the polishing head 120 and the pad conditioner 140.

The polishing head 120 is arranged over the polishing pad 114, and is configured to support and rotate a workpiece, such as a wafer 130. The polishing head 120 may be configured to hold or grip the wafer 130. The polishing head 120 is coupled to another spindle (or a shaft) 122. The spindle 122 is operable to be rotated by a motor or any other suitable driving mechanism. The rotation of the polishing head 120 and the rotation of the platen 112 may be independently controlled. The rotational direction of the polishing head 120 or the rotational direction of the platen 112 can be clockwise or counterclockwise. In some embodiments, the apparatus 100 further includes a retainer ring (not shown) for retaining the wafer 130 to be polished. The retainer ring is operable to prevent the wafer 130 from sliding out from under the polishing head 120 as the polishing head 120 moves.

The pad conditioner 140 may be configured to condition the polishing surface 114A of the polishing pad 114. The pad conditioner 140 includes an arm 142, a body 144 and a disk 146. The disk 146 is a polishing disk for performing pad dressing or pad conditioning. The body 144 is coupled to the disk 146. The arm 142 holds the body 144 and is configured to move the pad conditioner 140 over and across the polishing surface 114A of the polishing pad 114. The body 144 couples the arm 142 to the disk 146. In some embodiments, the arm 142 is configured to exert a downward force against the disk 146 through the body 144.

The slurry introduction device 150 may include one or more nozzles (not shown) arranged over the polishing pad 114, and may be configured to introduce slurry 152 to the polishing pad 114 through the nozzle(s). In some embodiments, the slurry 152 includes chemical and abrasive components. The composition of the slurry 152 may include abrasives to provide mechanical polishing forces, and include chemicals such as oxidizer to react with the material on the wafer 130 to be polished. The composition of slurry 152 may be selected depending on the material of the wafer 130 or the overlying film to be polished. For example, various types of the slurries 152 may be used for oxide, metal, and poly-silicon according to the type of object to be polished.

The measurement unit 160 may be configured to measure the planarity of to-be-polished wafer surface of the wafer 130. The measurement unit 160 may be disposed in the polishing wheel assembly 110. Referring to FIG. 1C, FIG. 1C is a top view of the apparatus 100, in accordance with some embodiments of the present disclosure. For the sake of clarity only the measurement unit 160, the polishing pad 114 and the wafer 130 are illustrated in FIG. 1C. The measurement unit 160 may be arranged in a place where the measurement unit 160 crosses a center 132 of the wafer 130 as the polishing pad 114 rotates. Thus, the measurement unit 160 may be able to measure the planarity of the whole surface of the wafer 130 along different routes running through the diameter of the wafer 130. In some embodiments, the measurement unit 160 is a wafer surface planarity sensor. The measurement unit 160 may be coupled to an analysis unit 162, such as a real-time thickness profile analysis module. The analysis unit 162 may be configured to analyze the planarity of to-be-polished wafer surfaces as measured by the measurement unit 160.

Referring to FIG. 1A or FIG. 1B, the temperature sensor 190 may be configured to measure the temperature distribution of the polishing pad 114. In some embodiments, the temperature sensor 190 is coupled to the analysis unit 162. The analysis unit 162 may be configured to analyze the temperature distribution of the polishing pad 114 as measured by the temperature sensor 190.

it should be noted that FIG. 1A is a schematic view showing a status of the apparatus 100 before the polishing head 120 starts to press the wafer 130 against the polishing pad 114. In other words, the wafer 130 is not being polished as shown in FIG. 1A. It also should be noted that FIG. 1B is a schematic view showing a status of the apparatus 100 during which the polishing head 120 presses the wafer 130 against the polishing pad 114. In other words, the wafer 130 is being polished as shown in FIG. 1B.

As depicted in FIG. 1B, during the polishing operation, the polishing pad 114 rotates about an axis 102. and the disk 146 rotates about an axis 104. The platen 112 and the disk 146 may rotate in the same direction or in different directions. In some embodiments, the platen 112 may be vertically movable with respect to the pad conditioner 140 such that the polishing pad 114 may contact the disk 146 for performing pad conditioning.

Still referring to FIG. 1B, during the polishing operation, the polishing pad 114 coupled to the polishing platen 112 and the wafer 130 carried by the polishing head 120 are both rotated at predetermined rates. Meanwhile, the spindle 122 provides down force, which is exerted against the polishing head 120, and thus is exerted against the wafer 130, thereby contacting the polishing pad 114. Thus, the wafer 130 or an overlying film (not shown) over the wafer 130 is polished. The slurry introduction device 150 may introduce the slurry 152 on the polishing pad 114 before or during the polishing operation.

FIGS. 1D-1E are a schematic view and a top view, respectively, of the platen 112, in accordance with some embodiments of the present disclosure. Referring to FIGS. 1D and 1E, the platen 112 may include one or more zones 113 and one or more heating elements 170 respectively disposed in the one or more zones 113.

As depicted in FIGS. 1D and 1E, the platen 112 includes a zone 113a disposed at the center of the platen 112 and a zone 113i disposed near the periphery of the platen 112. The platen 112 further includes zones 113b, 113c, 113d, 113e, 113f, 113g and 113h disposed between the zone 113a and the zone 113i. In some embodiments, the zones 113b to 113h have ring shapes. In some embodiments, the zones 113b to 113h are concentric rings.

Referring to FIG. 1E, the zone 113a includes a radius W1 and the zone 113i includes a width W9. In some embodiments, the radius W1 of the zone 113a is substantially equal to the width W9 of the zone 113i, but the disclosure is not limited thereto. In some embodiments, the radius W1 of the zone 113a is greater than the width W9 of the zone 113i.

The zone 113e includes a width W5. In some embodiments, the width W5 of the zone 113e is substantially equal to the width W9 of the zone 113i. In some embodiments, the width W5 is greater than the width W9. In some embodiments, the width W5 of the zone 113e is substantially equal to the radius W1 of the zone 113a. In some embodiments, the width W5 is greater than the radius W1.

The zone 113b includes a width W2, the zone 113c includes a width W3, the zone 113d includes a width W4, the zone 113f includes a width W6, the zone 113g includes a width W7, and the zone 113h includes a width W8. In some embodiments, the width W2, the width W3, the width W4, the width W6, the width W7 and the width W8 are substantially the same. In some embodiments, the radius W1, the width W2, the width W3, the width W4, the width W5, the width W6, the width W7, the width W8 and the width W9 are substantially the same.

Referring to FIGS. 1D and 1E, the platen 112 includes a heating element 170a disposed in the zone 113a, a heating element 170b disposed in the zone 113b, a heating element 170c disposed in the zone 113c, a heating element 170d disposed in the zone 113d, a heating element 170e disposed in the zone 113e, a heating element 170f disposed in the zone 113f, a heating element 170g disposed in the zone 113g, a heating element 170h disposed in the zone 113h, and a heating element 170i disposed in the zone 113i. In some embodiments, the heating elements 170a-170i are equally spaced. apart from each other. In some embodiments, the platen 112 includes conductive materials, such as aluminum alloy, and the like. In some embodiments, each of the heating elements 170 includes a heating coil. The heating elements 170 can provide heat via resistive heating, such as by passing a current or voltage through a resistor until a pre-determined temperature is reached.

Referring to FIG. 1E, the measurement unit 160 may be mounted on the platen 112. In some embodiments, the measurement unit 160 may be arranged at a middle location between the center of the platen 112 and the circumference of the platen 112, e.g., in the zone 113e of the platen 112. Thus, as the platen 112 and polishing head 120 rotate with respect to each other during the polishing operation, the measurement unit 160 substantially scans through a diameter of the to-be-polished surface of the wafer 130 along time, and can continuously monitor the heights of these surfaces as it passes over the wafer 130.

FIG. 1F is a cross-sectional view of the platen 112 taken along line A-A in FIG. 1D, in accordance with some embodiments of the present disclosure. Referring to FIG. 1F, the apparatus 100 may further include a control unit 172 coupled to control elements Z1, Z2, Z3, Z4 and Z5. The control unit 172 may include a processing unit such as a CPU, an FPGA, or a microcontroller. In some embodiments, the control unit 172 includes software modules, hardware modules (e.g., application specific integrated circuits (ASICs) or combinations of hardware and software modules. In some embodiments, the control unit 172 further includes a memory to store instructions of control functions to be executed by the processing unit. In some embodiments, the memory can be physically present in control unit 172.

In some embodiments, the individual heating elements 170a-170i are controlled by different control elements Z1 to Z5. For example, the control element Z1 is coupled to the heating element 170e in the zone 113e. The control element Z2 is coupled to the heating element 170d in the zone 113d and the heating element 170f in the zone 113f. The control element Z3 is coupled to the heating element 170c in the zone 113c and the heating element 170g in the zone 113g. The control element Z4 is coupled to the heating element 170b in the zone 113b and the heating element 170h in the zone 113h. The control element Z5 is coupled to the heating element 170a in the zone 113a and the heating element 170i in the zone 113i. The presented coupling configuration is for illustration purposes only, and other coupling configurations between the control elements Z1 to Z5 and the zones 113 are also within the contemplated scope of the present disclosure.

In some embodiments, the control elements Z1-Z5 are configured to control temperatures for respective heating elements 170. The control unit 172 may be configured to control a temperature difference between the control elements Z1-Z5. In sonic embodiments, the control unit 172 is a multi-zone temperature control module.

In some embodiments, during the polishing operation, a temperature of the zone 113d is tuned to be substantially equal to a temperature of the zone 113f. In some embodiments, a temperature of the zone 113c is tuned to be substantially equal to a temperature of the zone 113g. In some embodiments, a temperature of the zone 113b is tuned to be substantially equal to a temperature of the zone 113h. In some embodiments, a temperature of the zone 113a is tuned to be substantially equal to a temperature of the zone 113i. In some embodiments, a temperature of the zone 113e is tuned to be substantially equal to the temperature of the zone 113d. In some embodiments, the temperature of the zone 113c is tuned to be greater than the temperature of the zone 113d. In some embodiments, the temperature of the zone 113b is tuned to be greater than the temperature of the zone 113c. In some embodiments, the temperature of the zone 113a is tuned to be substantially equal to the temperature of the zone 113d or zone 113c.

FIG. 1G is a schematic view of the apparatus 100 and FIG. 1H is a top view of the polishing pad 114, in accordance with some embodiments of the present disclosure. For the sake of clarity only the polishing pad 114 and the platen 112 are illustrated in FIG. 1G. Referring to FIGS. 1G and the platen 112 may include one or more regions 115 corresponding to the zones 113 thereunder.

Referring to FIG. 1H, the polishing pad 114 includes a region 115a disposed at the center of the polishing pad 114 and a region 115i disposed near the periphery of the polishing pad 114. The region 115a and the region 115i correspond to the zones 113a and 113i, respectively. The polishing pad 114 further includes regions 115b, 115c, 115d, 115e, 115f, 115g and 115h disposed between the region 115a and the region 115i. The regions 115b, 115c, 115d, 115e, 115f, 115g and 115h are corresponding to the zones 113b, 113c, 113d, 113e, 113f, 113g and 113h, respectively. In some embodiments, the regions 115b to 115i have ring shapes. In some embodiments, the regions 115b to 115i are concentric rings.

As depicted in FIG. 1H, the region 115a includes a radius R1 and the region 115i includes a width R9. In some embodiments, the radius R1 of the region 115a is substantially equal to the radius W1 of the zone 113a. In some embodiments, the radius R1 of the region 115a is substantially equal to the width R9 of the region 115i.

The region 115e includes a width R5. In some embodiments, the width R5 of region 115e is substantially equal to the width R9 of the region 115i. In some embodiments, the width R5 is greater than the width R9. In some embodiments, the width R5 of the region 115e is substantially equal to the radius R1 of the region 115a. In some embodiments, the width R5 is greater than the radius R1. In some embodiments, the width R5 of region 115e is substantially equal to the width W5 of the zone 113e.

The region 115b includes a width R2, the region 115c includes a width R3, the region 115d includes a width R4, the region 115f includes a width R6, the region 115g includes a width R7, and the region 115h includes a width R8. In some embodiments, the width R2, the width R3, the width R4, the width R6, the width R7 and the width R8 are substantially the same. In some embodiments, the radius R1, the width R2, the width R3, the width R4, the width R5, the width R6, the width R7, the width R8 and the width R9 are substantially the same. In some embodiments, the radius R1, the widths R2-R9, the radius W1 and the widths W2 to W9 are substantially the same.

As discussed previously, the polishing pad 114 is coupled to the polishing platen 112 during the polishing operation. The polishing pad 114 may be heated by the heating elements 170 in the platen 112. The polishing pad 114 may be adjusted to different temperatures in different regions 115 according to the temperature of the heating elements 170. In some embodiments, a temperature distribution of the polishing pad 114 is adjusted by the control unit 172. The temperature distribution of the polishing pad 114 may be adjusted by the control unit 172 through the control elements Z1-Z5 and the heating elements 170.

In the present example, only nine heating elements 170 are shown in the platen 112; however, the number of heating elements and the arrangement of the heating elements can be altered according to various applications. Further, the number of zones 113 and the arrangement of the zones 113 can also be altered according to the number of heating elements and the arrangement of the heating elements. In addition, the number of regions 115 and the arrangement of the regions 115 can also be altered according to the number of heating elements and the arrangement of the heating elements in the platen 112.

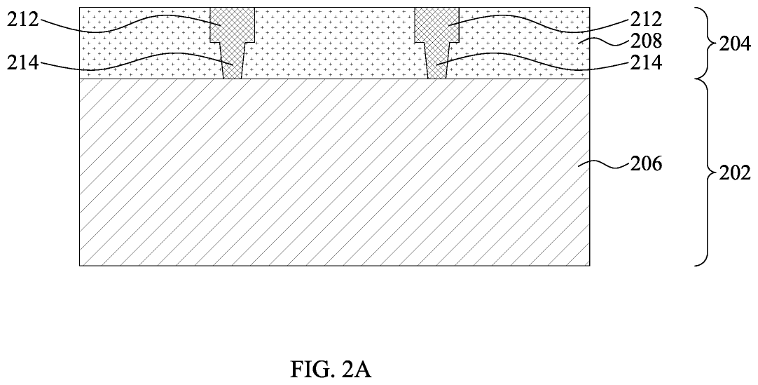

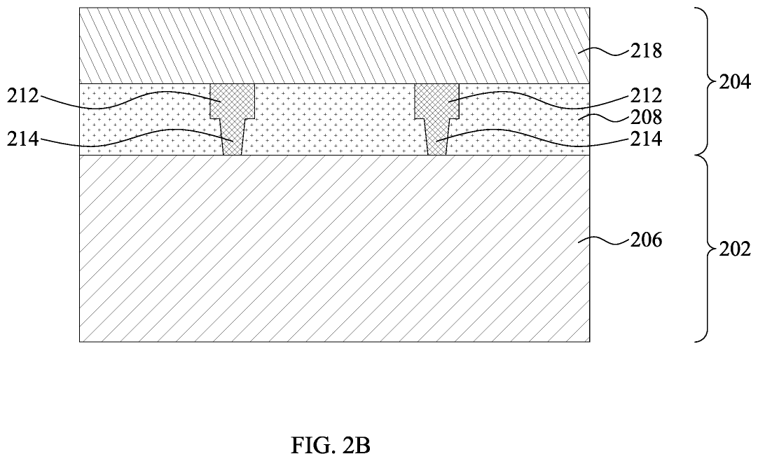

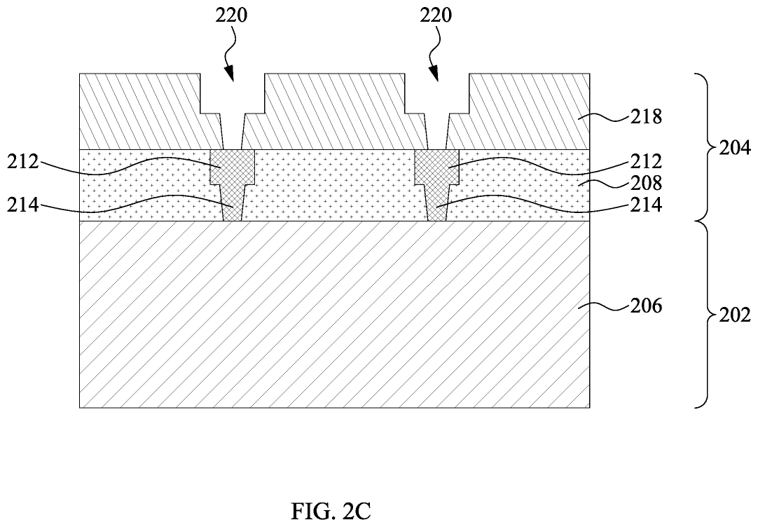

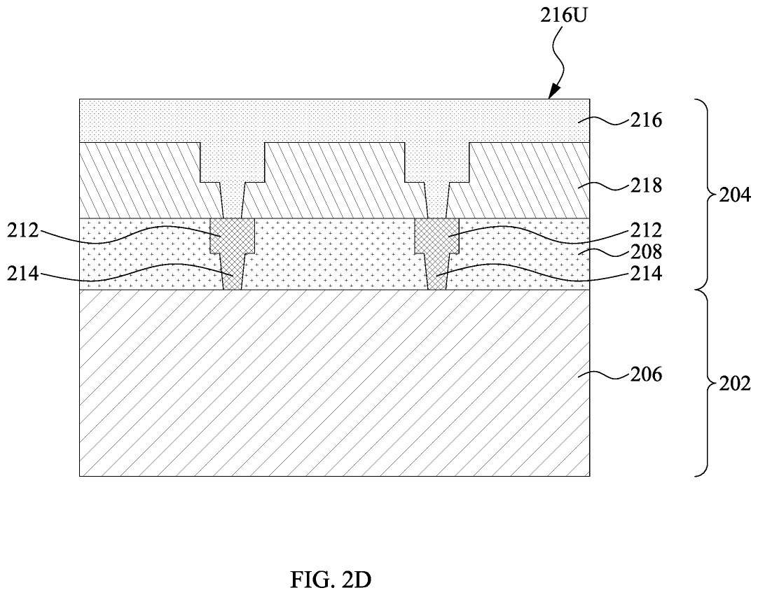

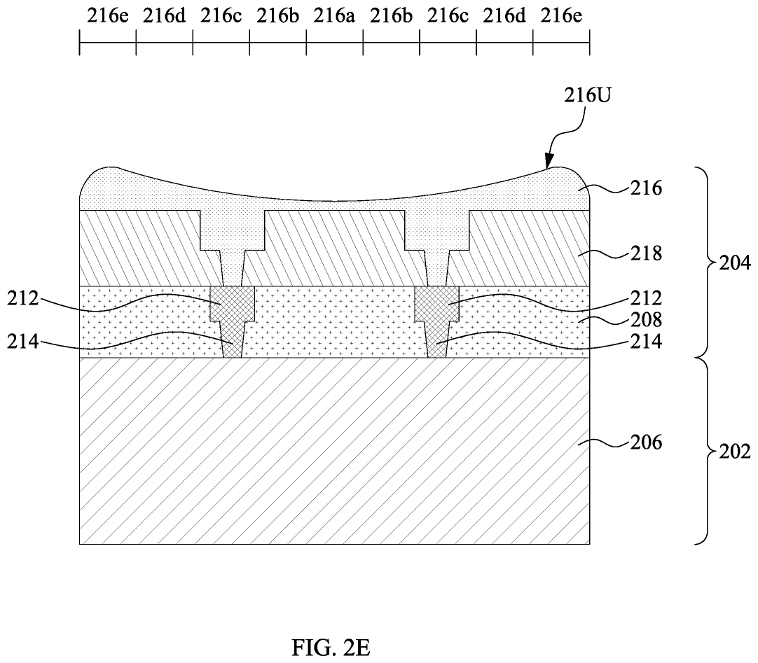

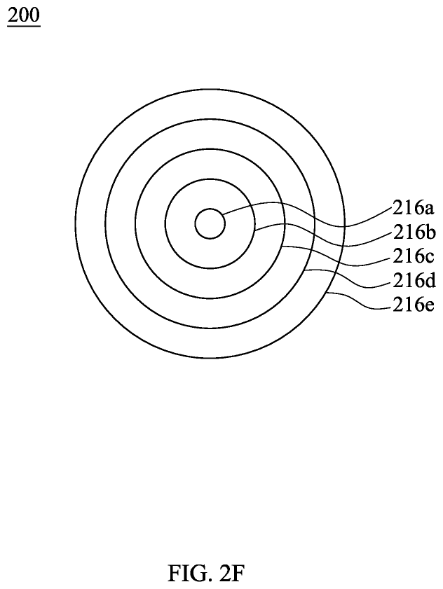

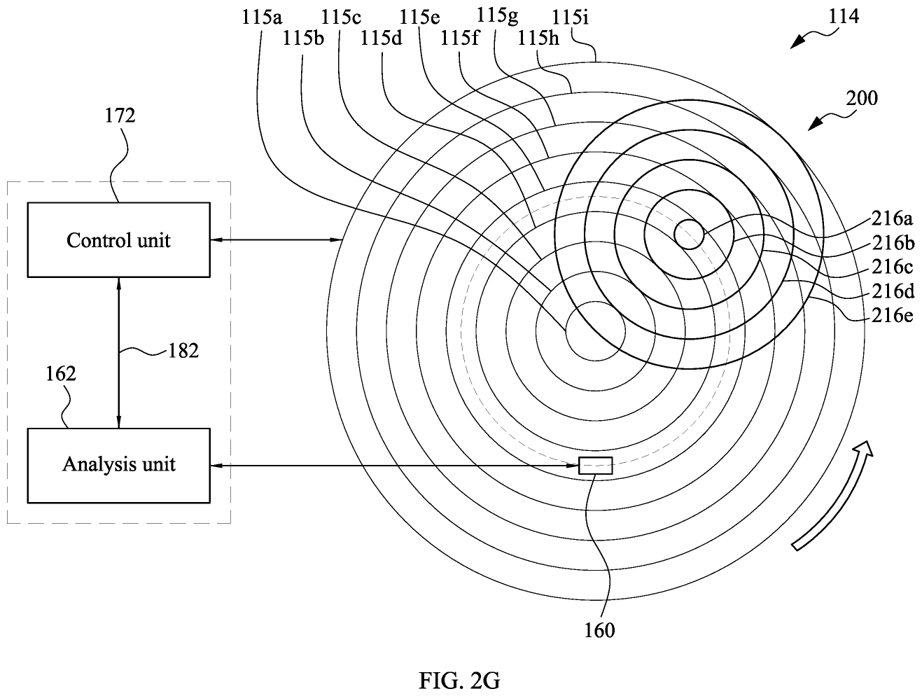

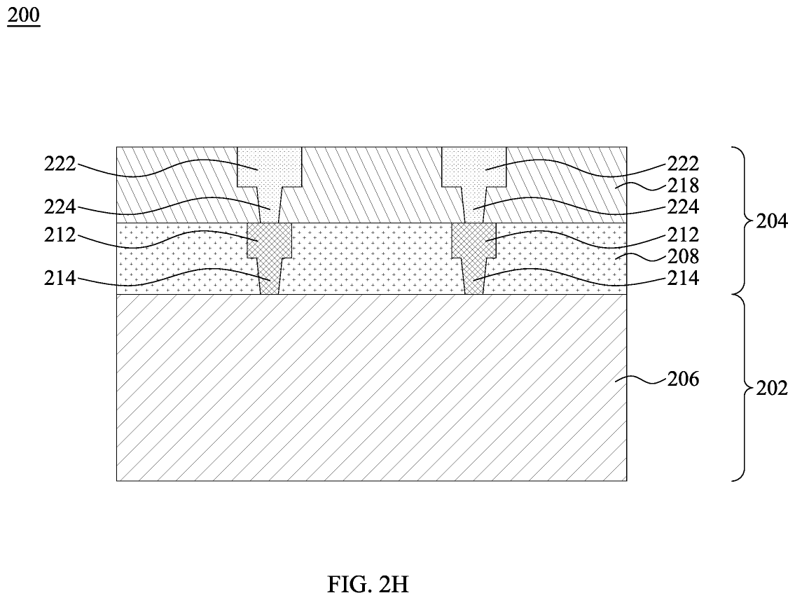

An exemplary method for forming a semiconductor structure by using the apparatus 100 is illustrated in FIGS. 2A-2F, which show sequential cross-sectional views at different stages of fabrication of a semiconductor structure 200.

Referring to FIG. 2A, a method for forming the semiconductor structure 200 includes providing an active structure 202 and an interconnect structure 204. The active structure 202 may be formed in a front-end-of-line (FEOL) phase, while the interconnect structure 204 may be formed in a back-end-of-line (BEOL) phase.

In some embodiments, the substrate 206 includes a semiconductor substrate. The substrate 206 may include various active or passive devices formed on a substrate 206. The active devices may include varies types of field effect transistors (FETs), such as planar FETS, fin FETs, and/or gate-all-around (GAA) FETs. The substrate 206 may further include local interconnects in some embodiments. In some embodiments, the passive devices include electric components such as capacitor, inductor, resistor, and diode. In some embodiments, the substrate 206 includes an interlayer dielectric layer (not shown) disposed over the substrate 206. In some embodiments, components such as conductive line layers, source vias, drain vias and gate contact plugs are formed in the interlayer dielectric layer.

The interconnect structure 204 is disposed over the active structure 202. In some embodiments, the interconnect structure 204 is disposed over the interlayer dielectric layer. In some embodiments, the interconnect structure 204 includes one or more dielectric layers 208, in which various conductive lines 212 and conductive vias 214 are embedded in the dielectric layers 208. The dielectric layer 208 may be referred. to as an inter-metallization dielectric (IMD) layer. In some embodiments, the dielectric layer 208 is formed of a low-K dielectric material, such as phosphosilicate glass (PSG), borophosphosilicate glass (BPSG), fluorosilicate glass (FSG) or the like. The conductive via 214 may electrically connect the conductive line 212 thereunder to the conductive line 212 thereon. The conductive lines 212 and conductive vias 214 are configured to form a conduction path to electrically interconnect the devices in the substrate 206 or electrically connect these devices in the substrate 206 to the overlying layers. In some embodiments, the conductive line 212 and conductive via 214 include conductive materials, such as W, Al, Cu, AlCu, Ti, Ta, TiN, TaN, and the like.

In some embodiments, the formation of the interconnect structure 204 involves one or more polishing operations, which will be discussed in greater detail below. Referring to FIG. 2B, a dielectric layer 218 is formed over the dielectric layer 208. The dielectric layer 218 can be formed by any suitable operations, such as chemical vapor deposition (CVD), physical vapor deposition (PVD), atomic layer deposition (ALD), or spin-coating. The dielectric layer 218 covers on the dielectric layer 208 and provides electric isolation between the conductive line 212 and overlaid conductive features. The dielectric layer 218 may be formed of similar materials as those for the dielectric layer 208.

Referring to FIG. 2C, one or more openings 220 are formed in the dielectric layer 218. The openings 220 may be formed by performing photolithography and etching operations on the dielectric layer 218. The openings 220 may include a stacked structure including a trench and a via over the trench. In some embodiments, a layer of photoresist is formed over dielectric layer 218 by a suitable process, for example, lithography or other alternatives, and patterned to form a photoresist feature by a proper photolithography patterning method. In some embodiments, a photolithography process may include forming a photoresist layer over dielectric layer 218, exposing photoresist to a pattern, performing a post-exposure bake process, and forming a masking element including the photoresist. In some embodiments, a dual-damascene technology is utilized where an intermediate etch stop layer may be formed as a hard mask for the stacked trench-via structure of the openings 220.

Subsequently, the openings 220 may then be etched using an etching operation. The etching operation may include dry etching, wet etching, and/or other etching methods (e.g., reactive ion etching). The etching operation may also be either purely chemical (plasma etching), purely physical (ion milling), and/or combinations thereof.

After the openings 220 are formed on the dielectric layer 218, the photoresist may be stripped thereafter. Subsequently, a diffusion barrier layer (not shown) may be optionally formed on the bottom and sidewalls of the openings 220. A typical diffusion barrier metal or alloy includes tantalum, nickel, hafnium, niobium, zirconium, vanadium, tungsten, and titanium tungsten. In addition, conductive ceramics is also considered, such as indium oxide, copper silicide, tungsten nitride, and titanium nitride. A suitable deposition process for forming the diffusion barrier layer as previously discussed can be used, such as CVD, ALD and PVD.

Referring to FIG. 2D, a conductive layer 216 is filled into the openings 220 of the dielectric layer 218, The conductive layer 216 may include similar materials as those for the conductive line 212 and conductive via 214. The conductive layer 216 is formed to cover the dielectric layer 218. In some embodiments, the conductive layer 216 covers the entire exposed surface of the dielectric layer 218. In some embodiments, the conductive layer 216 is formed on the dielectric layer 218 by sputtering, CVD, PVD, or plasma-enhanced CND (PECVD), etc.

In some embodiments, after the operation of forming the conductive layer 216 on the dielectric layer 218, a polishing operation is performed to remove excess portions of the conductive layer 216 to form a conductive line 222 and a conductive via 224 as shown in FIG. 2F.

Referring to FIG. 1B and FIG. 2E, during the polishing operation, the slurry 152 is dispensed to the polishing pad 114. In some embodiments, the measurement unit 160 (shown in FIG. 1C) is configured to measure the thickness profile of the conductive layer 216 during the polishing operation by measuring the contour of the upper surface 216U of the conductive layer 216. The conductive layer 216 may have non-uniformity polishing removal rates in different portions.

In some embodiments, the centers of the conductive layer 216 have higher polishing removal rates than those near the edges of the conductive layer 216, in other words, the surface of the conductive layer 216 may have a concave profile during the polishing operation. In alternative embodiments, the edges of the conductive layer 216 have higher polishing removal rates than those near the centers. In other words, the surface of the conductive layer 216 may have a convex profile during the polishing operation. The non-uniform removal rates may be attributed to various factors. For example, the slurry 152 may not be dispensed uniformly across the surface 114A of the polishing pad 114. This will result in non-uniformity of the removal rates in different locations of the conductive layer 216. Furthermore, the non-uniform removal rate may also result from the non-uniform pressure applied to different locations of the wafer 130 by the polishing head 120. Thus, the conductive layer 216 may experience non-uniform pressure during the polishing operation, leading to non-uniform polishing performances.

FIG. 2F is a top view of the semiconductor structure 200 during the polishing operation. In some embodiments, FIG. 2F can be considered as the top view of the upper surface 216U of the conductive layer 216. As discussed previously, the upper surface 216U of the conductive layer 216 may have non-uniform removal rate. The conductive layer 216 may be partitioned into five regions 216a, 216b, 216c, 216d and 216e according to the zones 113.

In some embodiments, the multiple regions 216a, 216b, 216c, 216d and 216e are identified based on the differences in the structure features within the relevant wafer surface areas. For example, the region 216e of the conductive layer 216 is relatively high, and the region 216a of the conductive layer 216 is relatively low. In alternative embodiments, the structure features include, but are not limited to, the density or ratio of various metal features versus dielectric features, the relative sizes of the metal features and the dielectric features, the metal materials of the metal features, and/or whether or not a surface layer of a zone requires a further fabrication process before reaching the polishing target. The multiple zones may be identified with reference to structure features other than the listed examples. The structural features affect the polishing removal rate of the individual features in a polishing operation and affect how the individual features change during the polishing operation. The region 216e of the conductive layer 216 have lower polishing removal rate compared to that of the region 216a.

In some embodiments, the removal rate is closely related to the temperature at which the polishing is performed. As such, to reduce the non-uniform polishing rates, in the proposed scheme, the temperature distribution of the polishing pad 114 are adjusted to compensate for different removal rates in different locations of the wafer 130. For example, if the removal rate in one region of the conductive layer 216 is deemed relatively low, this location is heated to a higher temperature to increase the removal rate in this region.

FIG. 2G is a schematic view showing the semiconductor structure 200 during the polishing operation. For the sake of clarity only the polishing pad 114 and the semiconductor structure 200 are illustrated in FIG. 2G. Referring to FIG. 2G, the control unit 172 can adjust temperatures of respective heating elements 170 in the platen 112 to achieve a desirable temperature distribution of the polishing pad 114. The temperature distribution of the polishing pad 114 may be adjusted to compensate for the removal rate differences between different regions of the conductive layer 216. The surface 114A of the polishing pad 114 is proximate to the upper surface 216U of the conductive layer 216. In some embodiments, the polishing removal rate of the polishing pad 114 is proportional to the temperature on the surface 114A of the polishing pad 114, the region-wise temperature control scheme helps to provide accurate planarity control of the polishing operation.

In some embodiments, if a to-be-polished wafer surface (e.g., the region 216e of the conductive layer 216 in FIG. 2E) is relatively high (e.g., present as a hillock), i.e., the thickness of the region 216e is relatively greater than that of its neighboring regions, the temperature of the corresponding region 115a or 115i of the polishing pad 114 can be increased to a temperature relatively higher than its neighboring temperature control regions 115. The temperature of the region 115a or 115i of the polishing pad 114 can be increased by the heating element 170a or 170i in the zone 113a or 113i and controlled by the control element Z5 as shown in FIG. 1F.

In some embodiments, if a to-be-polished wafer surface (e.g., the region 216a of the conductive layer 216 in FIG. 2E) is relatively low (e.g., a valley), i.e., the thickness of the region 216a is relatively less than that of its neighboring regions, the temperature of the corresponding region 115e of the polishing pad 114 can be decreased to a temperature relatively lower than its neighboring temperature control regions 115. The temperature of the region 115e of the polishing pad 114 can be decreased by the heating element 170e in the zone 113e and controlled by the control element Z1 as shown in FIG. 1F.

Accordingly, the proposed temperature-controlled polishing scheme enables independent control of the temperatures for the individual to-be polished wafer surfaces quickly by a fast control-feedback loop, such that the polishing temperatures are tailored to their respective polishing removal rates during polishing, thereby providing a planar surface in an efficient way.

in some embodiments, during the polishing operation, the measurement unit 160 measures the level of planarity of respective to-be-polished wafer surfaces (e.g., regions 216a-216e). For example, the measurement unit 160 measures the heights of the regions 216a-216e. As this profile is measured, a feedback signal is provided regarding the relative heights or the level of planarity of the respective to-be-polished wafer surfaces. The analysis unit 162 may analyze the planarity of to-be-polished wafer surfaces as measured by the measurement unit 160.

A feedback path 182 couples the analysis unit 162 to the control unit 172. Based on the retrieved data of planarity of the respective to-be-polished wafer surfaces, the control unit 172 can change temperatures for respective control elements Z1-Z5. The control elements Z1-Z5 may control temperatures for respective heating elements 170, and the temperature distribution of surface 114A of the polishing pad 114 can be adjusted. Thus, the to-be-polished wafer surface may be polished at different temperatures.

In some embodiments, the temperatures of the respective control elements Z1-Z5 can be adjusted in real-time. Hence, as the upper surface 216U of the conductive layer 216 is polished, its thickness is reduced over time, and the corresponding thickness profile is measured repeatedly until the desired thickness is reached. Throughout this polishing operation, the temperature of the individual control elements Z1-Z5 can be independently changed to limit the height variation between neighboring to-be-polished wafer surfaces. Polishing is completed when the conductive layer 216 reaches a predetermined thickness.

Referring to FIG. 2H, after the polishing operation, conductive line 222 and conductive via 224 are formed in the dielectric layer 208. The conductive line 222. and conductive via 224 may be formed to electrically couple the conductive line 212 and the conductive via 214 in the dielectric layer 208 to the overlying layers (not shown).

The apparatus and the method of the present disclosure are not limited to the above-mentioned embodiments, and may have other different embodiments. To simplify the description and for the convenience of comparison between each of the embodiments of the present disclosure, components in each of the following embodiments that are discussed previously are labelled with identical numerals. For convenience of comparing the difference between the embodiments, the following description will detail the dissimilarities among different embodiments and the identical features will not be repeated.

FIG. 3 is a schematic view of an apparatus 300, in accordance with some embodiments of the present disclosure. Many aspects of the apparatus 300 may be similar to the apparatus 100, and their descriptions are hereby omitted for brevity. Referring to FIG. 1A and FIG. 3, the apparatus 300 is different from the apparatus 100 in that the apparatus 300 includes a conduit 304 and a control unit 306.

In some embodiments, the apparatus 300 is disposed in a chamber 302. In some embodiments, the chamber 302 substantially surrounds the platen 112, the polishing pad 114, and the wafer 130. In some embodiments, the chamber 302 includes a material having a low thermal conductivity.

In some embodiments, the conduit 304 is disposed in the chamber 302. The conduit 304 may be coupled to the control unit 306. The control unit 306 may be configured to control a temperature of the water in the conduit 304. The control unit 306 may include a processing unit such as a CPU, a FPGA, or a microcontroller. In some embodiments, the control unit 306 includes software modules, hardware modules (e.g., application specific integrated circuits (ASICs) or combinations of hardware and software modules. In some embodiments, the control unit 306 includes a memory to store instructions of control functions to be executed by the processing unit. In some embodiments, the memory can be physically present in control unit 306.

Thermal-conductive materials, such as water, can be introduced to the conduit 304 and heated by the control unit 306. The temperature distribution of the polishing pad 114 may be adjusted by the heat provided by the conduit 304. In some embodiments, the control unit 306 is used to adjust the temperature of the space in the whole chamber 302, while the control unit 172 can be used for local temperature tuning on the polishing pad 114. In some embodiments, the control unit 306 is used to uniformly adjust the temperature of the space in the chamber 302 before the polishing operation. For example, the conduit 304 may be used in a warmup stage before the polishing operation starts. In some embodiments, the control unit 306 is used to uniformly adjust the temperature of the space in the chamber 302 during the polishing operation. In some embodiments, the adjustment of the temperature in the chamber 302 by the control unit 306 is performed simultaneously with the tuning of the local temperature by the control unit 172. In some embodiments, the adjustment of the temperature of the chamber 302 by the control unit 306 is performed prior to the tuning of the local temperature by the control unit 172. In some embodiments, the polishing removal rate is proportional to temperature, and thus this temperature control scheme may help to increase the polishing removal rate.

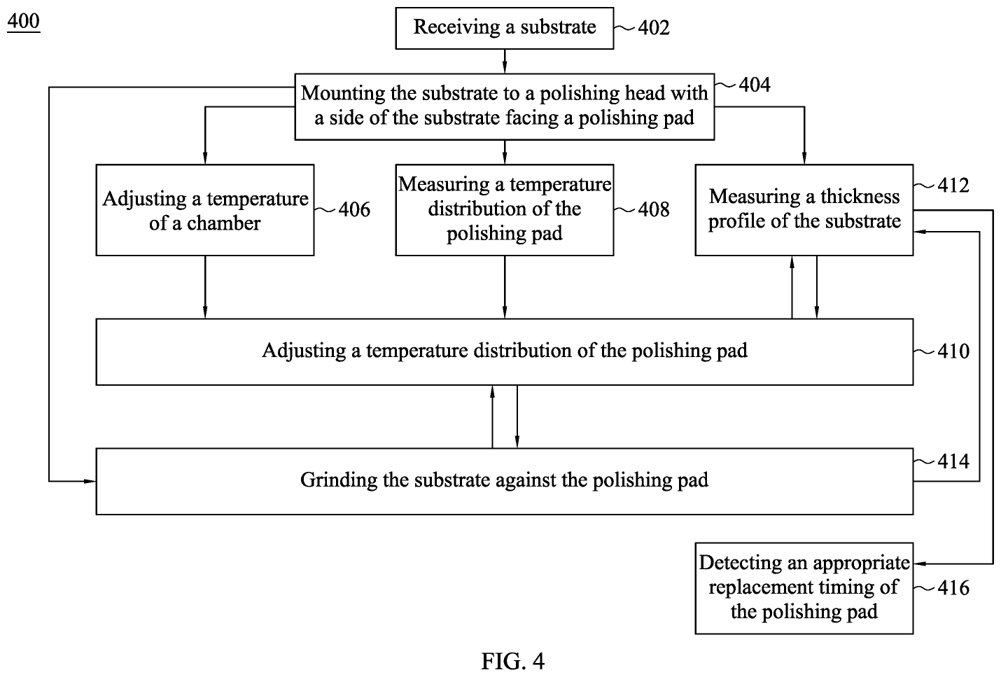

FIG. 4 is a flowchart of a method 400 for forming a semiconductor structure, in accordance with some embodiments of the present disclosure. The method 400 includes operations 402, 404, 406, 408, 410, 412, 414, and 416. It is understood that additional operations can be provided before, during, and after the method 400, and some of the operations described can be replaced or eliminated for other embodiments of the method. It should also be understood that the order of the operations in the method 400 can be altered according to different implementations.

At operation 402, a substrate is received. In some embodiments, the substrate is received in a chamber. The substrate may be the wafer 130 as discussed in FIGS. 1A-1B or the semiconductor structure 200 as discussed in FIG. 21),

At operation 404, the substrate is mounted to a polishing head with a side of the substrate facing a polishing pad. In some embodiments, the polishing pad defines one or more regions. The polishing head and the polishing pad may be referred to the polishing head 120 and the polishing pad 114 as discussed in FIG. 1A.

At operation 406 the temperature of a chamber is adjusted. The chamber may be referred to the chamber 302 as discussed in FIG. 3. In some embodiments, the temperature of the chamber may be adjusted by a control unit, such as the control unit 306. In some embodiments, the temperature of the chamber is adjusted to increase a temperature of the polishing pad. The operation 406 is an optional operation and may be omitted according to different implementations.

At operation 408, a temperature distribution of the polishing pad is measured. In some embodiments, the temperature distribution of the polishing pad is measured by the temperature sensor 190 as discussed in FIG. 1A. In some embodiments, the operation 406 and 408 are performed simultaneously. In some embodiments, the operation 406 is performed prior to the operation 408. The operation 408 is an optional operation and may be omitted according to different implementations.

At operation 410, the temperature distribution of the polishing pad is adjusted. In some embodiments, the temperature distribution of the polishing pad is adjusted by the control unit 172 as discussed in FIG. IF or FIG. 2G. In some embodiments, the temperature distribution of the polishing pad is adjusted, in which heat is provided by the conduit 304 as discussed in FIG. 3. In some embodiments, the operation 406 and the operation 410 are performed simultaneously. In some embodiments, the operations 406, 408 and 410 are performed simultaneously. In some embodiments, the operation 410 is performed in response to the measurement result of the operation 408.

In some embodiments, the method 400 further includes determining a temperature distribution of the polishing pad prior to the operation 410. In some embodiments, the temperature distribution of the polishing pad is adjusted in response to the determined temperature distribution.

In some embodiments, temperatures of one or more regions of the polishing pad may be adjusted or kept without change according to the thickness profile measurement result. As discussed in FIG. 2G, the polishing pad 114 may include regions 115a to 115i. The temperatures of the regions 115a to 115i of the polishing pad 114 may be adjusted either individually or in combination. In some embodiments, the method 400 further includes adjusting the temperature of the one of the regions and maintaining the temperature of another region. For example, if the surface of a polished region (e.g., the region 216a of the conductive layer 216 in FIG. 2E) is relatively low, the temperature of the corresponding region 115e of the polishing pad 114 can be maintained as its current temperature. If the surface of another polished region (e.g., the region 216e of the conductive layer 216 in FIG. 2E) is relatively high, the temperature of the corresponding region 115a or 115i of the polishing pad 114 can be adjusted.

In some embodiments, the method 400 further includes keeping the temperature of the one region and the temperature of another region from elevating if the thickness profile of the substrate reaching a predetermined profile specification or a predetermined range. For example, if the surfaces of different polished regions are substantially planar to each other according to the specification, the temperatures of the corresponding regions of the polishing pad are kept without change.

At operation 412, a thickness profile of the substrate is measured. In some embodiments, the thickness profile of the substrate is measured by a measurement unit 160 as discussed in FIG. 1C or FIG. 2G. In some embodiments, the operation 412 and the operation 410 are performed simultaneously. In some embodiments, the operation 410 is performed prior to the operation 412. In some embodiments, the performing of the operation 410 prior to the operation 412 may help to increase the polishing removal rate quicker. The operation 412 is an optional operation and may be omitted according to different implementations.

In some embodiments, the operation 412 is performed prior to the operation 410. In some embodiments, the operation 410 is performed in response to the operation 412. In some embodiments, the temperature distribution of the polishing pad is determined in response to the operation 412, and the operation 410 is performed after the temperature distribution of the polishing pad is determined. In some embodiments, the method 400 further includes measuring an initial thickness profile of the substrate. In some embodiments, the operation 410 is performed in response to the initial thickness profile of the substrate.

At operation 414, the substrate is grinded against the polishing pad. A polishing head along with the substrate is engaged to the polishing pad to remove an excess portion of the substrate. In some embodiments, the substrate is grinded against the polishing pad as discussed in FIG. 1B or 2E. In some embodiments, the operation 414 is performed prior to the operation 410 or the operation 412. In some embodiments, the operations 410 and 412 are performed prior to the operation 414; however, during the operation 414, the method continues to perform operations 410 and 412 to adjust the temperature distribution of the polishing pad and to measure the thickness profile of the substrate continuously.

At operation 416, an appropriate replacement timing of the polishing pad is detected. In some embodiments, if the measured thickness profile of the polished substrate still does not meet the specification, it is determined that the polishing pad needs to be replaced. In some embodiments, if the measured thickness profile of the substrate does not meet the specification after the operation 410, it is determined that the polishing pad needs to be replaced. The operation 416 is an optional operation and may be omitted according to different implementations.

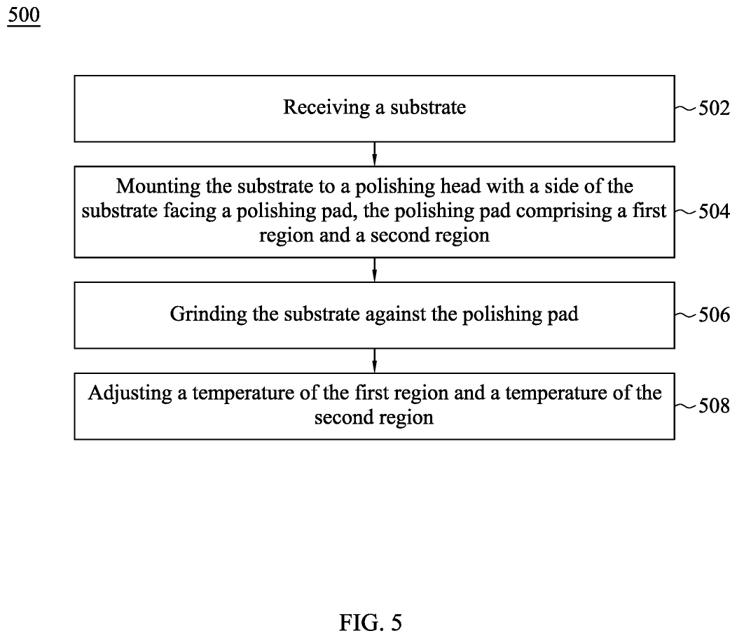

FIG. 5 is a flowchart of a method 500 for forming a semiconductor structure, in accordance with some embodiments of the present disclosure. It is understood that additional steps can be provided before, during, and after the method 500, and some of the steps described can be replaced or eliminated for other embodiments of the method. It should also be understood that the order of the operations in the method 500 can be altered according to different implementations.

The method 500 includes an operation 502 where a substrate is received. The method 500 further includes an operation 504 where the substrate is mounted to a polishing head with a side of the substrate facing a polishing pad. In some embodiments, the polishing pad includes a first region and a second region. The method 500 further includes an operation 506 where the substrate is grinded against the polishing pad. The method 500 further includes an operation 508 where a temperature of the first region and a temperature of the second region are adjusted.

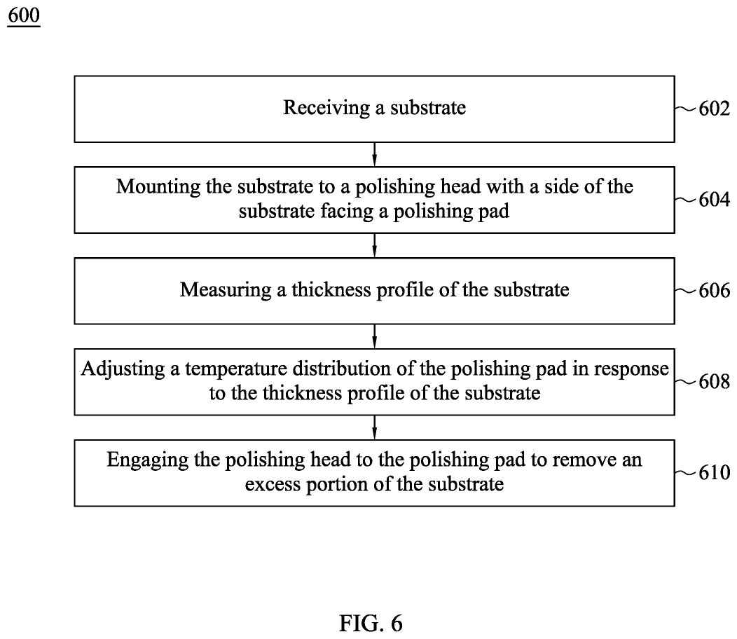

FIG. 6 is a flowchart of a method 600 for forming a semiconductor structure, in accordance with some embodiments of the present disclosure. It is understood that additional steps can be provided before, during, and after the method 600, and some of the steps described can be replaced or eliminated for other embodiments of the method. It should also be understood that the order of the operations in the method 600 can be altered according to different implementations.

The method 600 includes an operation 602 where a substrate is received. The method 600 further includes an operation 604 where the substrate is mounted to a polishing head with a side of the substrate facing a polishing pad. The method 600 further includes an operation 606 where a thickness profile of the substrate is measured. The method 600 further includes an operation 608 where a temperature distribution of the polishing pad is adjusted in response to the thickness profile of the substrate. The method 600 further includes an operation 610 where the polishing head is engaged to a polishing pad to remove an excess portion of the substrate.

In the present disclosure, an apparatus and a method forming a semiconductor structure are provided. The method includes adjusting a temperature distribution of the polishing pad. The polishing removal rate for the individual to-be polished wafer surfaces can be independently varied according to the temperature distribution of the polishing pad, thereby providing uniform planarization.

In some embodiments, a method for forming a semiconductor structure is provided. The method includes receiving a substrate; mounting the substrate to a polishing head with a side of the substrate facing a polishing pad, the polishing pad comprising a first region and a second region; grinding the substrate against the polishing pad; and adjusting a temperature of the first region and a temperature of the second region.

In some embodiments, a method for forming a semiconductor structure is provided. The method includes receiving a substrate; mounting the substrate to a polishing head with a side of the substrate facing a polishing pad; measuring a thickness profile of the substrate; adjusting a temperature distribution of the polishing pad in response to the thickness profile of the substrate; and engaging the polishing head to the polishing pad to remove an excess portion of the substrate.

In some embodiments, an apparatus for manufacturing a semiconductor structure, The apparatus includes a polishing head and a platen. The polishing head mounts a substrate. The platen holds a polishing pad against the polishing head. In some embodiments, the platen includes a first heating element, a second heating element and a control unit, The first heating element is disposed in a first region of the platen. The second heating element is disposed in a second region of the platen. The control unit is configured to control a temperature of the first region and a temperature of the second region.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
receiving a substrate;
mounting the substrate to a polishing head with a side of the substrate facing a polishing pad, the polishing pad comprising a first region and a second region;
grinding the substrate against the polishing pad; and
adjusting a temperature of the first region and a temperature of the second region.

2. The method according to claim 1, wherein the temperature of the first region is adjusted to be lower than that of the second region.

3. The method according to claim 1, wherein the polishing pad further comprises a third region between the first region and the second region, and the adjusting the temperature of the first region and the temperature of the second region further comprises adjusting a temperature of the third region.

4. The method according to claim 3, wherein the temperature of the third region is adjusted to be substantially same as that of the first region.

5. The method according to claim 1, wherein the first region and the second region are concentric rings arranged from a center of the polishing pad to a periphery of the polishing pad.

6. The method according to claim 5, wherein the polishing pad further comprises a fourth region between the second region and the periphery of the polishing pad, and the adjusting the temperature of the first region and the temperature of the second region further comprises adjusting a temperature of the fourth region.

7. The method according to claim 6, wherein the temperature of the fourth region is adjusted to be greater than that of the second region.

8. The method according to claim 1, wherein the temperature of the first region and the temperature of the second region are adjusted by heating a platen supporting the polishing pad.

9. The method according to claim 1, further comprising:
measuring a thickness profile of the substrate, wherein the temperature of the first region and the temperature of the second region are adjusted in response to the thickness profile of the substrate.

10. The method according to claim 9, wherein the thickness profile of the substrate is non-uniform.

11. The method according to claim 9, further comprising adjusting the temperature of the first region and maintaining the temperature of the second region.

12. The method according to claim 9, further comprising keeping the temperature of the first region and the temperature of the second region from elevating if the thickness profile of the substrate reaching a predetermined range.

13. A method for forming a semiconductor structure, comprising:
receiving a substrate;
mounting the substrate to a polishing head with a side of the substrate facing a polishing pad;
measuring a thickness profile of the substrate;
adjusting a temperature distribution of the polishing pad in response to the thickness profile of the substrate; and
engaging the polishing head to the polishing pad to remove an excess portion of the substrate.

14. The method according to claim 13, wherein the adjusting a temperature distribution of the polishing pad in response to the thickness profile of the substrate is performed prior to the engaging the polishing head to the polishing pad to remove an excess portion of the substrate.

15. The method according to claim 13, wherein the temperature distribution of the polishing pad are adjusted by a plurality of heating elements.

16. The method according to claim 13, further comprising:
measuring an initial thickness profile of the substrate.

17. The method according to claim 16, wherein the temperature distribution of the polishing pad is adjusted in response to the initial thickness profile of the substrate.

18. An apparatus for manufacturing a semiconductor structure, comprising:
a polishing head mounting a substrate; and
a platen holding a polishing pad against the polishing head, wherein the platen comprises:
a first heating element disposed in a first region of the platen;
a second heating element disposed in a second region of the platen; and
a control unit configured to control a first temperature of the first region and a second temperature of the second region.

19. The apparatus according to claim 18, wherein the second temperature is higher than the first temperature.

20. The apparatus according to claim 18, further comprising:
a measurement unit configured to measure a thickness profile of the substrate.
